(19) United States
(12) Patent Application Publication
(10) Pub. No.: US 2024/0136495 A1
(43) Pub. Date: Apr. 25, 2024

(54) METHOD FOR MANUFACTURING AN ELECTROCHEMICAL COMPONENT COMPRISING A LITHIUM METAL ANODE AND AN ION-CONDUCTIVE INORGANIC MATERIAL LAYER

(71) Applicant: PULSEDEON OY, Tampere (FI)

(72) Inventors: Ville KEKKONEN, Tampere (FI); Jari LIIMATAINEN, Tampere (FI)

(73) Assignee: PULSEDEON OY, Tampere (FI)

(21) Appl. No.: 18/547,323

(22) PCT Filed: Feb. 22, 2022
(86) PCT No.: PCT/FI2022/050115

§ 371 Date: Aug. 20, 2023

(30) Foreign Application Priority Data
Feb. 23, 2021 (FI) 20217036

(51) Int. Cl. H01M 4/04; C23C 14/08; C23C 14/18; C23C 14/20; C23C 14/28; C23C 14/56; C23C 14/58; C23C 16/40; C23C 28/00; H01G 11/06; H01G 11/50; H01G 11/86; H01M 4/134; H01M 4/1395; H01M 4/38; H01M 4/62; H01M 10/052; H01M 10/0525; H01M 10/0562

(52) U.S. Cl. CPC H01M 4/0423; C23C 14/08; C23C 14/18; C23C 14/20; C23C 14/28; C23C 14/562; C23C 14/5806; C23C 16/40; C23C 28/322; C23C 28/345; H01G 11/06; H01G 11/50; H01G 11/86; H01M 4/0407; H01M 4/0471; H01M 4/134; H01M 4/1395; H01M 4/382; H01M 4/62; H01M 10/052; H01M 10/0525; H01M 10/0562; H01M 2004/027

(57) ABSTRACT

A method for manufacturing a component of an electrochemical energy storage device utilizes lithium such that a coating method based on pulsed laser ablation is utilized in the production of an ion-conducting inorganic material layer on at least one surface of a lithium metal anode. At least one material layer is processed by thermal, mechanical, or thermomechanical treatment or by combination of any of these treatments after pulsed laser deposition. A roll-to-roll method can be used in the deposition, in which the substrate to be coated is directed from one roll to the second roll, and the deposition takes place in the area between the rolls. Moving and/or turning mirrors can be used to direct laser pulses as a beam line array to the surface of the target material.

### FIELD OF THE INVENTION

The invention is related to electrochemical energy storage devices utilising lithium such as batteries and capacitors, to their structure, and to manufacturing of materials used in these devices. The invention is especially related to the manufacturing method of at least one component of a lithium battery, lithium-ion battery, or lithium-ion capacitor, which component comprises ionically conductive inorganic solid electrolyte material, and which method utilises laser pulses and so-called pulsed laser deposition (PLD) method together with thermal, mechanical, and/or thermo-mechanical processing. The invention is further related to the use of the material containing ionically conductive solid electrolyte produced by utilising PLD method in batteries, capacitors, and other electrochemical devices.

### BACKGROUND OF THE INVENTION

As the number of mobile devices and electrically operated cars increases and the need for energy storage grows, development of the technologies utilised in energy storage to become better and safer is necessary. Li-ion batteries have been successful in very many applications, especially due to their good energy density and recharging possibilities compared, among others, to traditional Ni—Cd (Nickel-Cadmium) and Ni—Mn (Nickel-Manganese) batteries.

Today, the widely adapted lithium-ion battery technology is based on a positive electrode (cathode) made from transition metal oxide and on a carbon-based negative electrode (anode). Migration pathway for the Li-ions between the positive and negative electrodes is the electrolyte which in the contemporary solutions mostly is liquid, but transition to the use of solid-state electrolytes will be taking place in the future. Especially in the case of liquid electrolyte, a microporous polymer separator is used between the anode and cathode as an insulator which prevents the contact of the anode and cathode but allows the passage of ions through the separator membrane.

One of the next steps in the development of battery technologies will be the use of solid-state electrolytes. Replacing liquid electrolyte completely by solid material would considerably improve the safety of batteries as they wouldn't contain flammable organic solvent. Solid electrolytes would enable use of lithium-metal anode, which would increase the storage capacity of batteries. On the other hand, coating Li-metal-anode with solid electrolyte material would enable its use also in batteries which utilise liquid electolyte.

The energy density of Li-ion batteries is defined by the capability of the electrode materials to reversibly store lithium as well as by the amount of lithium available for ion exchange in the battery. One of the best ways to increase the energy density of Li-ion batteries is to use Li-metal instead of graphite, silicon, or silicon-containing composite materials as the active material of the negative electrode (anode). However, there are several technical challenges related to the use of lithium-metal anode of which the formation of lithium dendrites is one the most central challenges. Lithium dendrites are able to penetrate liquid electrolyte and separator membrane and to grow to the cathode thereby causing, for example, a short circuit and the resulting risk of fire or explosion.

Use of solid-state electrolytes provides a way to prevent or reduce the risk of dendrite growth, dendrites' ability to penetrate the separating material layer between the anode and the cathode and to prevent the formation of an electrical contact between the anode layer to the cathode layer. In order for the solid-state electrolyte layer to be able to prevent the growth of dendrites through the electrolyte layers, the mechanical properties, thickness, integrity, and structure of the electrolyte layer need to be appropriate. One essential mechanical property is the shear strength which can vary significantly among different inorganic solid electrolytes. Generally, many oxide materials have higher shear strength than, for example, sulfide materials, and oxides have better ability to resist dendrite growth.

The structural defects, such as cracks and pores, of the solid-electrolyte layers and especially those extending through the layers play an essential role. The manufacturing technology used in producing the electrolyte layer should guarantee minimal amount and size of the defects. Furthermore, the solid-electrolyte layers should be able to preserve a low defect density, i.a., during deformations and chemical reactions associated to use of batteries. Many of the inorganic solid-state electrolytes are fragile, and the risk of formation of defects or cracks extending even through the solid-electrolyte layer is high especially in the case the material has initial structural defects already after manufacturing.

For example, when powder-like materials are used for manufacturing of solid electrolyte layer, the materials need to be compacted and joined to lithium anode by means of temperature and pressure. Because lithium has a low melting point and it is relatively soft, it can be challenging to produce reliable joint and compaction of the solid electrolyte coating with good contact to the lithium anode. This is the reason why after manufacturing the solid-electrolyte layer readily has defects and structural weaknesses which reduce the layer's ability to prevent the penetration of lithium dendrites. On the other hand, if the solid-electrolyte layer is produced independently and compacted thermally and/or mechanically to be as dense as possible, one must be able to attach it to the anode material with good enough contact in order to avoid, i.a., the increase of the internal resistance at the interface to values too high and to avoid the detachment at the interface due to deformations and volume changes during the use of a battery.

The solid-electrolyte layer needs to have sufficient ionic conductivity such that it doesn't slow down the diffusion of Li ions through the electrolyte. If the thickness of the solid-electrolyte layer needs to be increased because of either limitations related to manufacturing method (for example manufacturing by sintering of powders) or the purpose to compensate the defects in the layer by increasing its thickness, the performance of the battery may decrease especially in the case of solid electrolytes with lower ionic conductivities. Thus, it would be advantageous to manufacture the solid-electrolyte layer in optimal thickness and of materials with high ionic conductivity by using methods providing minimal number of initial defects and good contact to lithium-metal anode.

Good adhesion of the solid-electrolyte layer to the lithium-metal anode is a crucial factor related to functionality of a battery. Poor adhesion or partial failure of the contact during operation slows down mobility of ions, increases internal resistance, and degrades performance of a battery. This is one of the disadvantages of manufacturing solid electrolyte from, i.a., inorganic powder-like materials.

The mechanical properties of solid-state elecrolytes have a significant impact on the stresses generated by the dimensional changes caused by charging and discharging during operation of a battery. The generated stresses could set off generation of micro- and macro-level fractures and degrade the conductivity in the battery crucially. Especially in the case of solid electrolytes with high Young's moduli, such as oxides (i.a., LLMO, where M=Zr, Nb, Ta), the generated stresses can be high. Solid electrolytes such as Li₇PaS₁₁, Li_{9.6}P₃S₁₂ and other solid electrolytes belonging to the LPS-system (meaning different compositions xLi₂S·(100−x)P₂S₅) as well as materials with thio-LISICON composition (e.g., Li₁₀GeP₂S₁₅, LGPS) all have low Young's moduli, and in the case of these solid electrolytes, the stresses generated at the interfaces and in the material layers are lower. However, consequently, these solid electrolytes also have a reduced ability to prevent the growth of Li dendrites through the solid-electrolyte layers.

On the other hand, the properties of high-ionic-conductivity solid electrolytes, such as materials belonging to the LPS-system or materials with thio-LISICON composition, are affected considerably by chemical composition, density, cohesion of particles as well as by the crystallinity of the material in question. If the coating process does not result in a completely dense material or if the contacts between different constituents of the material are not good, both the ionic conductivity and the mechanical durability will be poor. In addition, these will reduce the ability of the solidelectrolyte layer to prevent the growth of dendrites through the layer possibly leading to electrical contact and short circuit between the electrodes, which in the worst case scenario can result in a fire or explosion during operation of a battery.

In the case of the aforementioned solid electrolytes, the proportion of the crystalline phase in the structure has an effect on the ionic conductivity, and as the proportion of the crystalline phase increases the ionic conductivity will increase as well when these specific solid electrolytes are concerned. On the other hand, it is well known that a fully amorphous structure may have a better ability to prevent the growth of dendrites through the solid-electrolyte layer because an amorphous structure does not contain grain boundaries which could provide a path for dendrites to grow. Thus, one has to be able to optimize the degree of crystallization in the structure considering both the ability to prevent the growth of dendrites and the ionic conductivity,

Lithium is a reactive material and reacts with, i.a., oxygen and nitrogen as well as moisture in air. In addition, reactions with carbon dioxide in air may cause passivation of its surface and hinder its functionality as an electrode material. The use of lithium as a thin metal foil is complicated by the extremely challenging manufacturing by forming into a thin foil of under 50 micrometers in thickness, and thin lithium foils have limited availability and high prices. Furthermore, the lubricants used in the forming process contaminate the surface of lithium degrading its electrochemical properties. If lithium anode is assembled into a cell as a thin foil, its contact to other functional layers is essential.

In the case of the best solid electrolytes, such as materials belonging to the LPS-system or materials with thio-LISICON composition, one has to take into account the stability of the interfaces when the cell structure is such that these materials are in electrochemical contact with lithium metal. In many cases, in order to guarantee the stability, a layer of some other material with sufficiently high ionic conductivity has to be applied between the aforementioned solid elecrolytes and lithium metal. Alternatively, the surfaces of the solid electrolytes in question being in contact with lithium metal could be modified to be more stable by adjusting their crystalline structure or composition.

### SUMMARY OF THE INVENTION

The present invention discloses a method for producing a battery containing lithium-metal anode and at least one solid-electrolyte layer applied in lithium batteries, Li-ion batteries, and Li-ion capacitors, such that at least one solid-electrolyte layer is produced by using pulsed laser technology. The intentions of the method of the present invention are to prevent contaminations and environmental reactions of the key functional materials, such as lithium and solid electrolytes, to improve adhesion between different material layers, and to prevent the growth of lithium dendrites from the anode to the cathode through the separating layers. An essential feature of the method of the present invention is the unrestricted optimization of the thicknesses of the different material layers in order to improve the performance and reliability of a battery. Additionally, the micro-structures and compositions of the solid electrolytes are adjusted in the method such that one has the ability to optimize the ionic conductivity, homogeneity of the ionic conductivity throughout the material layer and at the interfaces, as well as the ability of the solid-electrolyte layer to prevent the growth of dendrites to cause, e.g, a short circuit.

A central feature of the present invention is to produce a solid-electrolyte layer by using pulsed laser technology and, as an alternative, to combine this coating process with the use pulsed laser ablation in one of the following optional approaches
Processing of the surface of a Li-metal anode foil by laser ablation in order to clean it and to shape its topography prior to applying solid-electrolyte layer
Producing a coating layer of Li anode by using pulsed laser ablation, after which a solid-electrolyte coating layer is produced by using the same method in a subsequent process step
Producing a coating layer of solid electrolyte on a separator membrane (cellulose, polymer, or glass fiber), after which a Li-anode coating layer is produced on top of the solid-electrolyte layer in a subsequent process step
Applying one of the aforementioned approaches in such a way that there are at least two solid-electrolyte layers which have been made of different materials such they have different degrees of crystallization
Applying one of the aforementioned approaches in such a way that between solid-electrolyte layers and/or between Li-anode layer and electrolyte layer, a material inherently other than an ionically conducting material, such as an inherently electrically insulating oxide, is applied
The manufacturing process is supplemented by the processing of at least one material layer by using laser or some other thermal treatment method in order to optimize the structure of the material layer
The manufacturing process is supplemented by mechanical processing of at least one material layer, for example by rolling method, in a subsequent process step after producing the material layer
The manufacturing process is supplemented by thermomechanical processing of at least one material layer, meaning simultaneous application of elevated temperature and mechanical processing
The manufacturing process is supplemented by thermal treatment of at least one material layer in order to adjust the microstructure, for example, in terms of the desired crystallinity
The manufacturing process can also be supplemented by several different complementary options, such as thermomechanical processing of one material layer and processing the following layer only by thermal treatment

With respect to the manufacturing method (pulsed laser ablation deposition, pulsed laser deposition, PLD) and the manufactured product (component of a Li-ion battery), the present invention relates to existing patent applications and granted patents which present the prior art:
Finnish patent application FI20175056 discusses manufacturing of anode materials and Finnish patent application FI20175057 discusses manufacturing of cathode materials by pulsed laser ablation deposition method. The applications disclose the utilization of laser ablation deposition in the manufacturing of layered and composite structures as well as the possibility, enabled by the methods, to realize a performance-improving combination of electrochemical, chemical, and mechanical properties in the electrodes of a Li-ion battery. In addition, these patent applications disclose doping of the electrode material with some other material by using a pre-doped target, separate targets, or sequential coating steps.
Finnish patent application FI20175058 discusses manufacturing of solid electrolyte materials by pulsed laser ablation deposition.
Patent application US20050276931A1 discloses manufacturing of electrochemical device based on thin films (thickness e.g. <10 μm) and multi-layer structures by pulsed laser ablation deposition.

In the method of the present invention, laser pulses are directed to a target material removing material from the target as atoms, ions, particles, or droplets or as combinations from this selection of species. The material ejected from the target is directed to the surface of the object to be coated resulting in a coating with the desired properties and thickness.

The quality, structure, quantity, size distribution, and energy of the material ejected from the target are controlled by the parameters used in laser ablation, these parameters include, among others, wavelength, power and intensity of the laser, temperature of the target, pressure of optional background gas, and, in the case of pulsed lasers, laser pulse energy, pulse length, pulse repetition rate, and pulse overlap. Furthermore, the microstructure and composition of the applied target materials can be tuned together with the selected laser parameters in order to produce the desired process, material distribution, and coating layer.

One significant advantage of laser ablation deposition is that it can be applied in processing of many different materials allowing for the production of different combinations of materials and microstructures. In addition, the coating process according to the method can be applied on a wide range of different substrates, including also sensitive materials. Owing to these benefits, the method provides freedom to realize the material selection and structures based mainly on the properties of the ideal end product and with less influence by the limitations of the manufacturing method. Depending on the material or combination of materials and the desired properties, the process parameters of laser ablation can be tuned in order to reach the desired microstructure and morphology. Especially in the case of multi-layer structure, such as those in components of Li-batteries, it is beneficial to produce the functional layers using one and same method without exposure of the different layers to the environment. This way the contaminations and environmental reactions can be minimized and an as good as possible adhesion between different layers can be achieved.

Pulsed laser ablation deposition allows for producing both dense and porous coating layers and also for tuning the porosity, particle size, and free surface area of the layer, all of which properties have significance in lithium batteries, Li-ion batteries, and Li-ion capacitors. In the case of lithium-metal anode and solid electrolyte, the goal is to produce materials as dense as possible and without defects. This needs to be taken into account when selecting the process parameters for both ion-conducting inorganic electrolytes and lithium-metal anodes.

High density of a material can can be achieved in many different approaches, and adjustment of the process parameters for producing as high as possible density is a material-specific task in which also reaching adequate adhesion and productivity need to be taken into account. Especially in the case of inorganic ceramic materials, the best level of density and flawlessness is typically achieved by generating highest possible degree of atomization and ionization of the target material without generation of particles by using laser pulses with short duration. Furthermore, it is necessary to guarantee, especially by minimizing the gas pressure in the deposition chamber, that the atomized and/or ionized material flow does not condense into particles during the flight from the target to the surface of the substrate. In addition, the formation of molten droplets could be detrimental for reaching a flawless coating, especially if the molten droplet has the time to solidify before hitting the substrate's surface, thus not being able to deform upon impact. Particles particularly detrimental for achieving high density are the ones which are detached from target without melting, atomization, or ionization. This type of material detachment is supported by fragile nature of the target and/or a target with an inhomogeneous structure allowing for ablation of different compositional regions taking place at different moments.

Metallic materials or relatively soft inorganic materials allow for achieving a dense structure also in the case the material flow from the target to the substrate is composed of molten droplets, condensed particles, or even detached particles. This is made possible by the kinetic energy of the particles and the heat generated by the process which both contribute to densification and atomic-level rearrangement of particles hitting the substrate.

An important material property of solid electrolytes is crystallinity which, depending on the material, has an impact especially on ionic conductivity and possibly on the ability to prevent the growth of dendrites. If the dendrites grow preferentially along grain boundaries, an amorphous, glassy micro-structure can slow down the growth rate. In addition, the grain boundaries can be micro-structural areas which are susceptible to the formation of defects, such as cracks, which contribute to the growth of dendrites. Furthermore, the composition of the material on the surfaces and in the proximity of grain boundaries may significantly differ from the primary corn position of the material, which has an effect on the electrochemical behavior of the interfaces and on the formation of detrimental structures of metallic lithium.

The crystallinity of the material produced by laser ablation can be controlled, for example, by adjusting the temperature of the process. Performing pulsed laser ablation using short pulses allows for promoting the formation of an amorphous structure. On the other hand, an amorphous structure can be transformed at least partially to crystalline not only by changing the process parameters but also by surface treatment by laser or by some other thermal treatment performed after the coating process. Owing to the controlled delivery of energy, laser processing also allows for processing a thin surface layer, which is beneficial in cases where the coating layer to be thermally treated is on the surface of a heat-sensitive material.

When using thermomechanical processing, it is possible to both densify solid-electrolyte layers and modify their micro-structure simultaneously. If the solid-electrolyte material in question comprises particles formed in pulsed laser deposition, the thermomechanical processing, such as hot rolling, will support also the adhesion between particles thus promoting ionic conductivity and mechanical durability, such as bendability. If the temporal duration of the thermomechanical processing is too short for generating, for example, the desired degree of crystallization in solid electrolytes, it is possible to continue the processing after the thermomechanical processing by thermal treatment for a long enough duration to reach the desired degree of crystallization.

Pulsed laser ablation can be utilised to produce many of the advantageous features described above based on this one process technology, even in single coating process step with certain prerequisite conditions. Alternatively, laser ablation process can also be realized in several sequences in a process line where, for example, electrode material layer is produced in the first phase and, for example, an ion-conducting protective layer or a solid-electrolyte layer is produced in the subsequent phase. These phases can be performed sequentially until the desired coating layer thickness has been produced.

A significant advantage of using pulsed laser technology is the possibility to accurately adjust the thickness of, for example, a solid-electrolyte layer or a lithium-metal anode. When a solid-electrolyte layer is produced of, for example, materials belonging to the LPS-system or materials with thio-LISICON composition, it is very difficult to produce thin layers of less than 10 micrometers in thickness by utilizing powder technology. Pulsed laser technology allows for producing layers of even less than 1 micrometer in thickness accurately.

In case it is desired, pulsed laser ablation technique can be used for producing a composite or an alloyed material, for example, a coating layer comprising electrode material and solid electrolyte, such that the coating layer is composed of electrodematerial particles embedded in a matrix of solid electrolyte. This way, it is possible to generate a gradient structure which can minimize the diffusion lengths and the stresses generated in the materials during use of a battery as well as provide unobstructed migration pathways for ions. In the gradient structure, the compositional proportions of the electrode material and electrolyte as well as of an optional electron-conducting material change as a function of distance when moving from the anode towards the cathode.

In principle, it is possible to use some or several of the previously described methods in combination with some other coating method, for example, as sequential process steps such that pulsed laser technology is utilised in the coating process step where it suits the best and another coating method is utilised to supplement pulsed laser ablation. This can be realized as consecutive process steps or as separate processes.

The coating process can be realized as roll-to-roll method or, for example, on sheets which are fed to the process line as successive sheets.

Considering productivity of high-volume products, it is essential to perform the deposition process by utilizing a wide laser-pulse (scan line) array which can be generated, for example, by moving or rotating mirrors as well as by using several laser sources. The laser pulse scan line ablates material from the target in the desired way and across the whole coating width, and the material flow is directed from the target onto the selected area on the surface of the object to be coated.

The inventive idea of the invention also comprises the final product manufactured using the method, i.e. a Li battery, a Li-ion battery, or a Li-ion capacitor, including all the required material layers, of which at least one layer containing ion-conducting solid electrolyte is manufactured by pulsed laser ablation deposition utilizing laser pulses.

### SHORT DESCRIPTION OF THE DRAWINGS

In the following, the invention will be described in more detail with reference to the accompanying drawings, in which

FIG. 1 illustrates the principle of the coating procedure with different physical components in an example of the invention,

FIG. 2 illustrates the principle of forming a fan-shaped array of parallel pulsed laser beams with an equipment setup of the invention,

FIG. 3 illustrates an example of the so-called roll-to-roll principle related to the coating process,

FIG. 4 illustrates in the format of a cross-section image the functional layers of a Li battery according to an exemplary embodiment in the case where the coating process is performed on lithium anode manufactured as a foil,

FIG. 5 illustrates in the format of a cross-section image the functional layers of a Li battery according to an exemplary embodiment in the case where the coating process is performed on copper current collector,

FIG. 6 illustrates in the format of a cross-section image the functional layers of a Li battery according to an exemplary embodiment in the case where the coating process is performed on separator membrane,

FIG. 7a illustrates a combinatorial coating method for composite coating layer (including also doped coating) by using two simultaneous material flows,

FIG. 7b illustrates a combinatorial coating method for alloyed-material coating layer by using two simultaneous material flows,

FIG. 8a illustrates the use of consecutive coating units for improving productivity,

FIG. 8b illustrates the use of consecutive coating units for improving productivity when manufacturing composite structures,

FIG. 8c illustrates the use of consecutive coating units for improving productivity when manufacturing doped materials.

### DETAILED DESCRIPTION OF THE INVENTION

In the method of the invention, the functional structures of a lithium battery, Li-ion battery, or Li-ion capacitor comprising lithium-metal anode are produced such that an ion-conducting inorganic coating layer produced by using pulsed laser technology (Pulsed Laser Deposition=PLD) is on the surface of lithium-metal anode.

In pulsed laser ablation, solid material is removed by short laser pulses duration of which can vary within the range from milliseconds down to femtoseconds. Pulsed laser (ablation) deposition (PLD) based on laser ablation typically involves use of laser pulses with durations of 100,000 ps at most (in other words 100 ns at most). In one embodiment, it is also possible to use ultrashort pulsed laser ablation deposition (so-called US PLD) method where the duration of laser pulses is 1000 ps at most. When deemed necessary, different laser parameters for different materials are used for producing the different material layers of a lithium battery, a Li-ion battery, or a Li-ion capacitor.

Removal of materials and generating a material flow from a target or multiple targets to the surface of the object to be coated is done by using laser pulses. In order to remove material from the target, the laser fluence (J/cm²) needs to be high enough on the surface of the target. The threshold fluence, known as ablation threshold, at which the material removal from the target initiates, is a material specific parameter value of which also depends, inter alia, on the laser wavelength and temporal duration of laser pulses. The typically used and available laser pulse energies have magnitude which requires the laser beam to be modified optically such that the area of the laser spot on the target surface is made smaller in order to reach high enough fluence. The simplest way to realize this is to place a focusing lens in the laser beam path at a suitable distance from the target. However, one needs to take into account that the laser pulse intensity has characteristic spatial and temporal distributions which depend on the laser and the optics used. In practice, neither the intensity, nor the fluence for that matter, has a perfectly homogeneous distribution within the laser spot on the target surface even if means for homogenizing the distribution were used. This can result in a situation where the ablation threshold is exceeded only in certain parts of the laser spot, and the size and proportion of the area exceeding the ablation threshold depend on the total laser energy being used.

Removal of material can take place in the form of atoms, ions, molten particulates, exfoliated particles, particles condensed from atoms and ions after ejection from target, or combinations of the some of the above. The mode of removal of the material and behavior of the material after removal from the target, such as the tendency to condensation, depend, inter alia, on how much the laser pulse energy density exceeds the ablation threshold. Depending on the material and on the requirements set for its structure and morphology of the coating layer, the parameters of the laser ablation can be adjusted. Suitable parameters can be defined specifically for each material to produce the desired coating layer. On the other hand, also the properties of the target, such as micro-structure and density influence the absorption of laser and on the ablation process as well as on the quality of the generated material flow and formation of particles.

In addition to a constant repetition rate of laser pulses, laser pulses can be delivered to the target as so-called bursts which are composed of a selected number of pulses at selected repetition rate. For example, 100 W of average laser power can be produced by individual 100-μJ laser pulses at 1-MHz repetition rate or by bursts composed of 10 pieces of 10-μJ laser pulses at 60-MHz repetition rate and with 1MHz burst repetition rate. It is also possible to control the pulse energy of individual pulses composing the burst.

Bursts, or laser-pulse packages, and the high pulse repetition rates enabled by bursts, are significant especially in the case of short laser pulses. By using bursts, one is able to change the interaction of the laser with the material and to control the properties of the ejected material. For example, the high repetition rates enable increasing the total energy of the material ejected from the target and reducing the amount or the size of particles in the ejected material, because part of the laser pulses interact directly with the cloud of ejected material instead of the solid surface of the target.

It is essential to notice that, after ejected from the target, changes in the structure, size distribution, and composition of the material can take place in the material flow before the material attaches to the substrate. The process of changes can be controlled, for example, by the atmosphere within the deposition chamber, i.e., the composition and pressure of the background gas, as well as by adjusting the travel distance of the material (from the target to the substrate).

Furthermore, additional energy can be introduced to the material flow, for example, by laser pulses, which can be realized also by using only a single laser source by means of the above-mentioned burst of laser pulses or high repetition rate. Laser pulses can be used for making potential particles in the material flow smaller and also for increasing the total energy and degree of ionization.

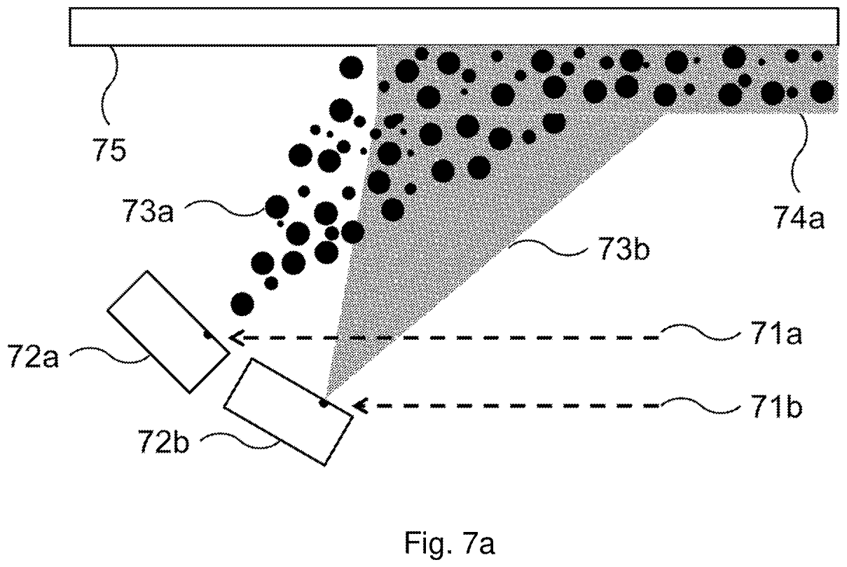

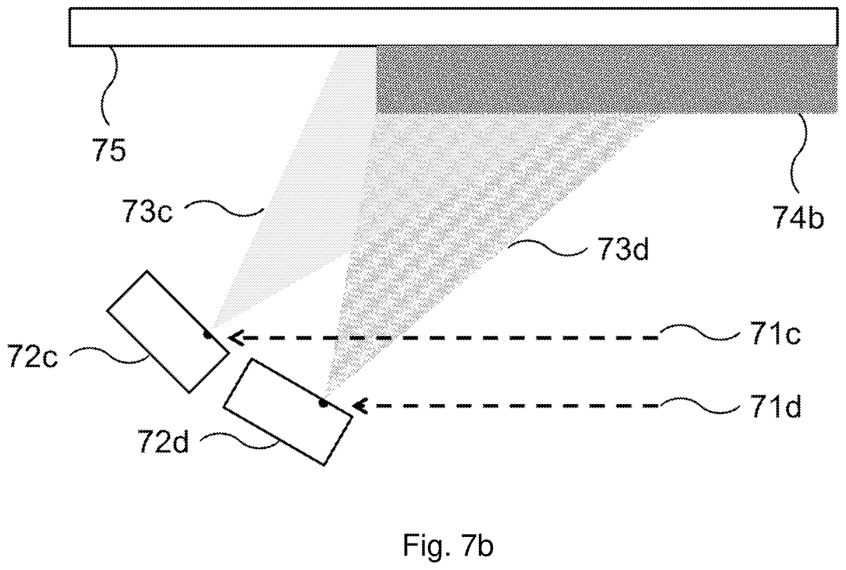

The composition of the material can be changed by using reactive background gas (for example, oxygen for oxides and nitrogen for nitrides) or by bringing together material flows from several different sources. By realizing laser ablation process simultaneously on several different targets and directing the material flows into the same volume it is possible to form compound-material coatings, composition of which can be adjusted flexibly on elemental level. This arrangement is presented in FIG. 7b. A special case of this kind of an arrangement is a composite target which has been produced, for example, by mixing two materials in powder form and compacting them into a solid piece. When laser pulses with high enough energy are directed to a target composed of two materials, ablation affects both materials as if the particles of the target were separate material sources, and material flows generated from these sources are able to interact and react with each other to form a new compound which condenses on the substrate to form a coating. Pulsed laser ablation deposition can be used in the above-mentioned compound-forming approach also in combination with other coating methods, in which case the other material flows can be generated by thermal evaporation or sputtering by ions or by electron beam.

During or after completion of the coating process, the crystal structure and adhesion (between the coating and substrate) of the produced coating can be affected by heating the substrate or by directing ion bombardment, light pulses, or laser pulses on the coating layer. In case of some materials, the processing of the layer produced by a coating process can be realized mechanically by introducing external pressure to the structure, for example, by using rolls.

In the method of the present invention, it is essential to produce a combination of functional materials by utilizing, at least in part, pulsed laser technology, which materials enable increasing significantly the energy density of a lithium-ion battery without shortening its working life. The central features of the invention are a lithium-metal anode produced by using a suitable technique, at least one ion-conducting inorganic material layer or solid-electrolyte layer produced by using pulsed laser technology on the surface of the lithium-metal anode, as well as an ion-conducting electrolyte, either solid or liquid, between the aforementioned material layers and the cathode material. In the case of a liquid electrolyte, it might be necessary to apply a porous separator membrane (suitable separator materials are, i.a., polymer, cellulose, ceramic, or glass fiber) which serves as a protective layer against the growth of dendrites and provides the required space for the liquid electrolyte between the cathode-material layer and the anode-material layer. On the other hand, also in the case of a solid electrolyte, a porous separator membrane (polymer, cellulose, ceramic, or glass fiber substrate) can function as a substrate and/or as a supporting framework into which a solid electrolyte is produced generating ion-conducting pathways through the porous substrate. In some cases, it might be beneficial to produce a coating of, for example, material containing ceramic particles on the porous substrate prior to applying the ion-conducting inorganic material layer. This approach allows for improving the mechanical properties of the porous substrate and its applicability to the coating process, as well as enables optional post-deposition treatments at high temperatures.

The cathode can be any cathode material applicable to be used in a Li-ion battery, materials such as lithium-containing transition-metal oxide such as LiCoO₂, LiMnO₂, LiMn₂O₄, LiMnO₃, LiMn₂O₃, LiMn₂₋ₓMₓO₂ (M=Co, Ni, Fe, Cr, Zn, Ta, 0.01<x<0.1), LiNiO₂, (M=Co, Ni, Fe, Mg, B, Ga, 0.01<x<0.3), LiNiₓMn₂₋ₓO4 (0.01<x<0.6), LiNiMnCoO₂, LiNiCoAlO₂, Li₂CuO₂; LiV₃O₈, LiV₃O₄, V₂O₅, Cu₂V₂O₇, Li₂Mn₃MO₈ (M=Fe, Co, Ni, Cu, Zn), various materials capable of storing lithium-ions within their structures (so-called intercalation cathode materials) such as TiS₃ and NbSe₃ and LiTiS₂, or some polyanion compound such as LiFePO₄. Other cathode materials are sulfur and materials based-on sulfur composites or sulfur: Li₂S, transition-metal sulfides MS₂ tai MS (M=Fe, Mo, Co, Ti, . . . ). Also other applicable materials and compounds, alloys, composites, or layered structures based on the materials can be utilised.

Single-element materials usually are without problems in terms of stoichiometry unless the material reacts with the atmosphere inside the deposition chamber. In case of multi-element compounds, stoichiometry control needs to be taken into account because change in composition might also induce changes in the structure and functionality of the material. Especially in the case of solid-electrolyte materials, which usually comprise even four or five different elements, controlling stoichiometry is essential in controlling their properties. If compositional changes take place in the PLD process in transforming the target into a coating layer, it is possible to take it into account, for example, by excess material in the target to compensate for the loss of certain element or several elements. Furthermore, adjusting the deposition atmosphere, meaning controlling of the partial pressures of the background gases, one can add, for example, oxygen or nitrogen if changes with respect to those elements are known to take place during the deposition process.

Laser ablation process enables different material and coating concepts to be produced even with one single method and equipment owing to the flexibility of the method and its applicability to different materials by selection of suitable parameters. This considerably reduces the required equipment-related investments for different battery material coating solutions, increases the speed of manufacturing and shortens delivery times, as well as reduces the number of errors in manufacturing and handling.

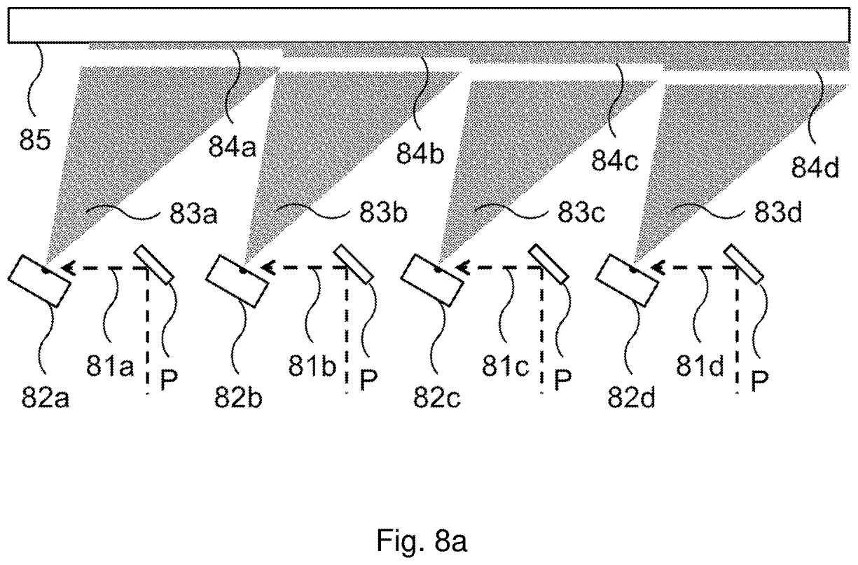

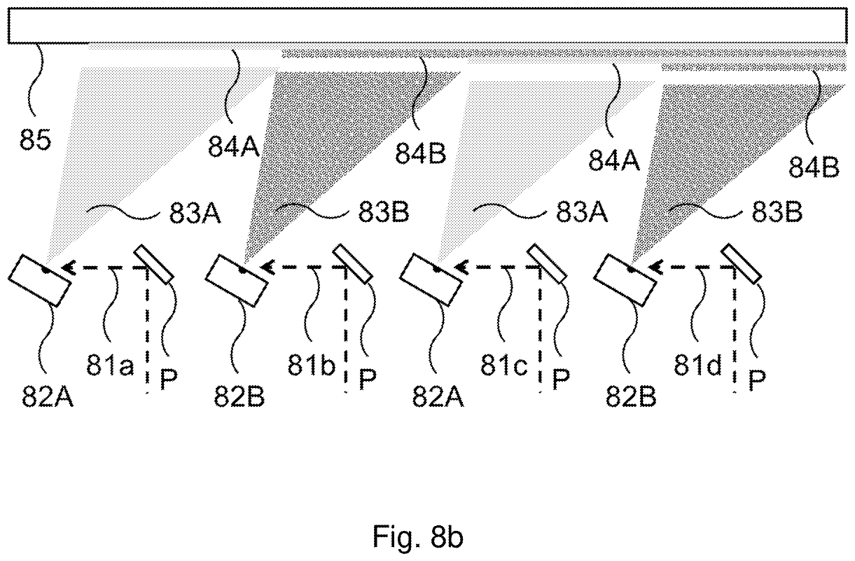

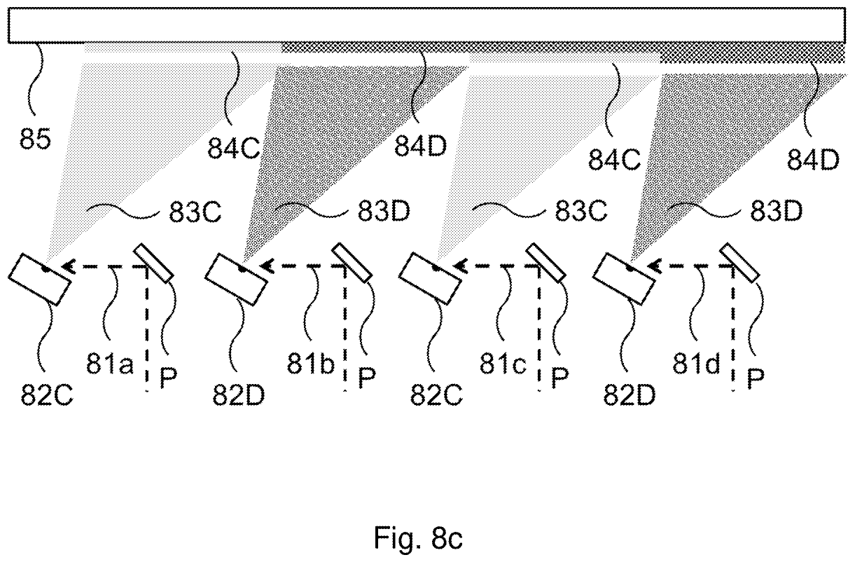

The method is applicable particularly in roll-to-roll manufacturing, where the substrate, for example a web of porous polymer or cellulose separator, ceramic or glass fiber, copper anode current collector or lithium-metal anode, is guided from a roll to the coating stations as a continuous web, after which the battery material coating layer is deposited on the web in the coating stations (there can be one or more units). The coating stations can be setup in a row also in such a way that either the same material or different materials are deposited in several coating stations consecutively increasing the productivity or in such a way that different materials are deposited in the coating stations to produce composite or multi-layer structures or to add dopant materials, for example materials improving electrical conductivity, on the surfaces of battery materials. These application alternatives have their own exemplary drawings presented in FIGS. 8a-c.

Instead of several coating stations in a row, the coating can alternatively be manufactured in roll-to-roll process such that the web to be coated first passes through the coating station, and a layer of the desired material is deposited on the web. As a next step, the movement direction of the web is reversed and the target material is changed in the coating station automatically, and deposition of another material is performed, the material being for example a dopant material (mixture material), second part of a composite material, second layer material of a layered material, and this process is repeated until the desired structure is complete.

The coating stations enable also production of different types of protective layers on the surfaces of different layers or, for example, only on the final layer of battery materials in order to, for example, prevent the dissolution of essential components of the material or the detrimental reactions with the electrolyte. A thin enough protective layer does not affect significantly the ionic conductivity, even if the material of the protective layer would not be intrinsically ion-conducting. These protective layers can improve the contact between the layers of electrode and electrolyte.

It is not necessary to use pulsed laser ablation deposition for the deposition of all the material layers, and other deposition and manufacturing methods of material layers can be included in the processing chain, if that is optimal from the overall approach point of view. Such supporting deposition and manufacturing methods include CVD (Chemical Vapor Deposition) technology, ALD (Atomic Layer Deposition) technology, and PVD (Physical Vapor Deposition) technology such as sputtering. Even in different regions within one same material layer, it could possibly be necessary and beneficial to produce a part of the layer by pulsed laser technology and another part by some of aforementioned other deposition methods.

The composition of the material detached by laser ablation must be preserved within appropriate range for the functionality of the coating. In principle, the pulsed laser technology, especially ultrashort pulsed laser technology, is a suitable method for minimizing disadvantageous changes in composition, for example, due to different type of evaporation or the non-simultaneous evaporation of doping substances. Especially by means of the ultrashort pulsed laser technology it is possible to minimize the melting of the material and the formation of extensive molten areas, which increase uneven material losses and impede the control of stoichiometry. In case of many target materials, restricting the duration of the laser pulses to under 5-10 ps is sufficient to minimize the melting of the target and excessive loss of doping components in laser ablation, if the overlapping of laser beams is minimal. At high repetition rates, the overlapping of laser pulses may cause the material to melt even if short pulse durations were used. A change in stoichiometry may cause a loss of the desired structure and appropriate functionality. In addition, in industrial manufacturing, the process must stay constantly stable, due to which also changes occurring in the target composition or other properties over long periods of time are detrimental. Controlling stoichiometry is an essential feature in production of ion-conducting solid-electrolyte materials which of the consist of even up to four or five different elements.

When manufacturing composite materials, layered structures or by doping the principal material of the coating with some other material, the optimum process parameters and circumstances of different materials are not necessarily the same. This must be taken into account when planning and combining different steps in the production process. If the intention is to manufacture a composite material using a combinatory solution, the laser parameters can be tailored optimally for different materials by using a different laser source for different materials, but in this case, it must be possible to ablate all materials sufficiently well in the same deposition atmosphere, because it can be difficult to adjust the deposition atmosphere separately when performing combinatory ablation. If it is necessary to adjust the coating atmosphere separately for all materials, this can be most easily realized in successive coating steps so that a deposition atmosphere advantageous for different materials can be controlled independently. Several such coating steps can be built in a process solution depending on the type of material distribution one desires to produce.

In certain situations, it is also possible to make the desired doping to an individual target material piece, and if the ablation thresholds of the materials in relation to each other and the condensation tendency in the chosen gas atmosphere are suitable, the composite structures can be manufactured by mixing the desired materials to the target material in a desired proportion.

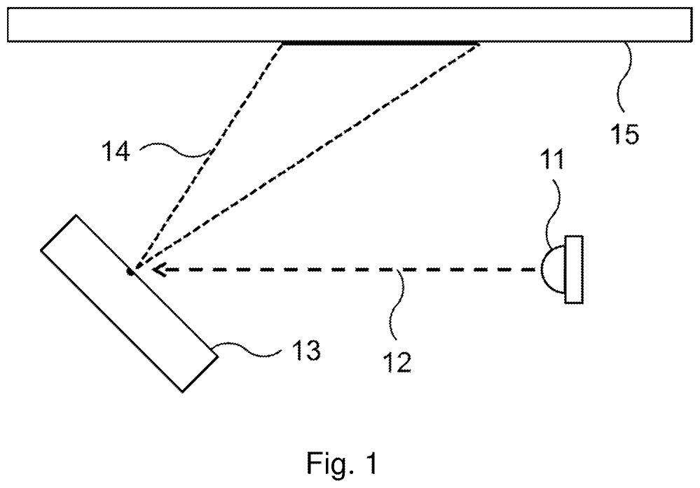

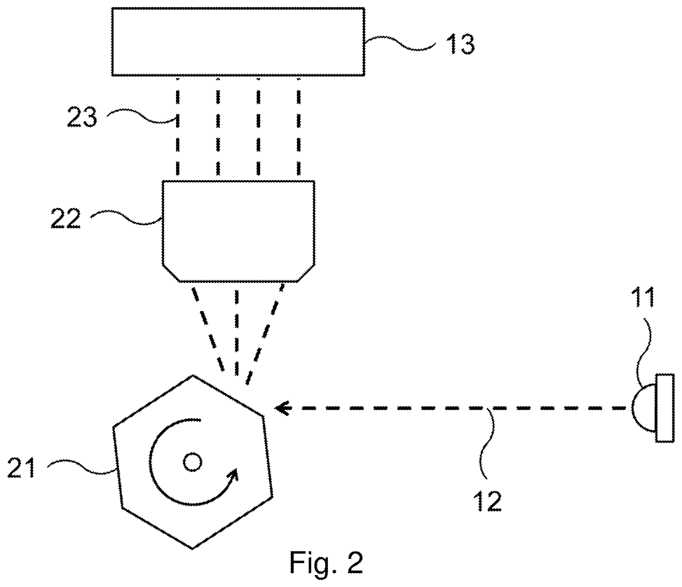

The basic principle of the method (pulsed laser ablation deposition, PLD) is illustrated in the view of principle in FIG. 1, in which the structural parts and directions of motion of the material included in the coating process are shown at a principled level. In FIG. 1, the energy source for the ablation process is the laser light source 11, from which laser light is directed as pulses 12 towards the target 13. The laser pulses 12 cause local detachment of material on the surface of the target 13 as particles or other respective fragments, which have been mentioned above. Thus, the material flow 14 is generated, which extends towards the object 15 to be coated. The object 15 to be coated can also be called a coating base or substrate. The correct alignment can be performed by setting the direction of the plane of the target surface 13 appropriately in relation to the object 15 to be coated so that the direction of the kinetic energy released in the form of plasma is towards the object 15 to be coated. The laser source 11 can be moved in relation to the target 13, or the target 13 in relation to the laser source 11, and the angle of the laser beams in relation to the surface of the target 13 can be varied. Optical components such as, for example, mirrors and lenses can be placed between the laser source 11 and the target 13. Furthermore, a separate optical arrangement can be placed between the laser source 11 and the target 13 for focusing and parallelizing the array of laser pulses hitting the target 13. There is a separate FIG. 2 of this arrangement.

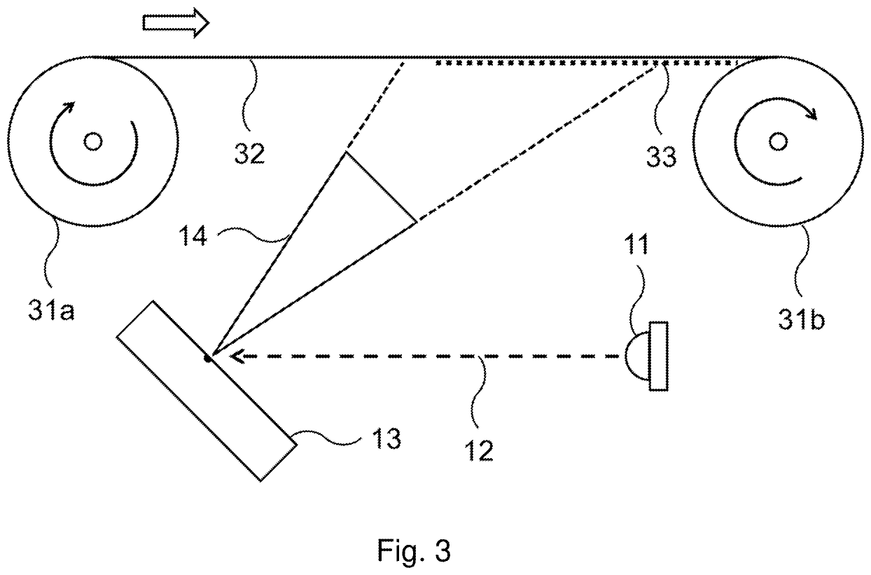

The material flow 14 in FIG. 1 can be fan-shaped so that a wider area can be coated on the area of the surface of the object 15 to be coated by one angle of orientation of the target 13 assuming that the material to be coated is not transferred laterally (seen from the figure). In another embodiment, the material to be coated is movable, and of this embodiment there is the separate FIG. 3.

Generally, in an example of ablation used in the invention, the detachment of the target surface material and transfer of material from the target to the substrate and/or to the previously formed material layer are achieved with laser pulses directed on the target, in which the duration of an individual laser pulse can be in the range 0.1-100000 ps. Advantageously the temporal duration of an individual laser pulse is in the range 0.1-1500 ps.

In an example of the invention, laser pulses can be generated at a repetition rate which is between 50 kHz-100 MHz.

The coating layer formed by the material detached by laser ablation and transferred as particles from the target to the substrate must form reliable bonding to the substrate or previously prepared material layer. This can be achieved by sufficient kinetic energy of the particles, which provides sufficient energy for forming bonds between different materials. In addition, in a particle-intensive material flow, it would be preferable to have a sufficient quantity of atomised and ionised material to support the formation of bonds between the particles.

A highly essential process parameter in laser ablation deposition when manufacturing porous coatings is the gas pressure used in the process chamber. Increasing the gas pressure promotes the formation and growth of particles during the material's flight from the target to the surface of the material to be coated. An optimal gas pressure may vary according to the gas or mixture of gases being used, to the type of material being coated and to the desired particle size distribution, porosity and adhesion between the particles, and the bonding of the particles to the rest of the material. For the selection and purity of the gas, one needs to take into account the potential reactions with the materials of the substrate, of the object to be coated, and of the target. In some cases, the reaction-sensitive surfaces can be protected from detrimental reactions with the residual gases in the deposition chamber by using an inert gase, such as argon, with high enough partial pressure in the deposition process.

In an embodiment, the laser ablation and deposition take place in a vacuum chamber, i.e., either in a vacuum or background gas, where a controlled pressure can be applied. A possible alternative is to set the pressure between 10⁻⁸-1000 mbar.

When pursuing porous coatings or an increase in porosity, a background gas pressure of 10⁻⁶-1 mbar is typically used. The relative significance of background gas varies depending on the density and total energy of the material flow and on the distance the material travels from the ablation point on the surface of the target to the surface of the object to be coated. If laser ablation is performed with so-called thermal ablation and local melting of the target material surface, a porous coating and a particle size of less than 1 μm can also be produced in a low background-gas pressure, because the formation of particles occurs through molten drops and not through condensation from atomised material. Further, a particle-based material flow can be achieved also by promoting the detachment of particles in the target material through selective energy absorption or partial cracking of target materials.

Thermal, mechanical, and thermomechanical processing of many materials used in lithium-ion batteries is possible and advantageous for optimizing the structure. These post-processing methods can be used for, for example, fixing imperfections generated in the pulsed laser deposition and this way for guaranteeing the density of of the coating layer as well as for adjusting the micro-structure.

In order to remove porosity in coating layer produced by pulsed laser technology, sufficient cold or hot forming can be applied to densify the structure. Reduction ratio is defined based on the residual porosity, and the use of heat can reduce the force required for forming. For example, in the case of solid electrolytes of the LPS-system or solid electrolytes having thio-LIS ICON structures, a temperature of 80-120° C. is already enough to reduce the force required in forming. It is necessary to reduce the force needed in forming, especially if the aforementioned solid electrolyte layers are produced on the surface of a mechanically weak material. In hot forming, it is crucial to heat the materials to be processed such that heat is not transferred to the substrate, especially if the substrate is heat sensitive. Heating of the material to be formed can be realized, for example, by using hot plates, hot calender, laser, and/or heat lamps either prior to the forming process and/or during the forming process such as in the case of hot calendering by using heated rolls during calendaring.

To control the crystallinity and to reduce the residual stresses of solid electrolytes, such as materials of the LPS-system or materials having thio-LISICON structure, heat treatment can be applied either directly after pulsed laser deposition or after mechanical or thermomechanical processing. In the case of the aforementioned solid electrolytes it is often required to generate controlled crystallization in order to optimize ionic conductivity and the ability to prevent the growth of dendrites. An amorphous structure might be the the most preferable to prevent the growth of lithium-metal dendrites through the solid-electrolyte layer. This is based on the absence of grain boundaries which, according to several studies, provide a pathway for dendrites to grow along. On the other hand, the ionic conductivity of an amorphous structure is not necessarily as good as that of an at least partially crystalline material. Heat treatment can generate crystals in a solid-electrolyte material, and the amount and size distribution of the crystals can be adjusted by combinations of temperature and processing times. Here, the amorphous or glassy material can be defined such that the portion of crystalline material it contains is less than 5 weight-% or 5 volume-10%.

For the solid electrolytes of the LPS-system, the suitable temperature range for controlling their crystallinity is 150-300° C. or higher, and, in addition, in the case of materials with thio-LISICON structures amount of suitable crystallinity can be increased in temperatures above 400° C. One has to take into account, that heat treatment needs to be performed in an environment which does not cause detrimental surface reactions in these solid electrolytes. Moisture and oxygen content of the heat-treatment environment is crucial. For example, the moisture level should preferably be below 5 ppm. Considering the temperature range in the case of multi-layer materials, one needs to take into account also the other material layers, such as lithium metal or various polymers, for which the processing temperature can be significantly less than 200° C. at most.

When optimizing properties of solid electrolytes, such as materials of the LPS-system or materials having thio-LISICON structure, it is also possible to optimize the crystallinity of the structure in the thickness direction of the solid-electrolyte layer. One option is to first manufacture the whole solid-electrolyte layer in amorphous phase by pulsed laser deposition, after which a controlled heat treatment is performed such that the structure crystallizes as the desired depth. If an amorphous surface is in contact with lithium metal, its amorphous structure without grain boundaries is very strong against the growth of dendrites. Alternatively, pulsed laser technology could be used first to produce a solid-electrolyte layer which will be processed by heat treatment to optimize the crystallinity of its structure. After this step, pulsed laser deposition is used for producing a thin amorphous solid-electrolyte layer, which functions as a contact surface for lithium-metal anode.

To improve homogeneity and productivity, it would be preferable to produce as wide a material flow as possible from the target to the substrate. In an example of the invention, this can be realized by distributing the laser pulses by turning mirrors to form a laser pulse array in one plane, which results in formation of a line on the plane of the surface of the target. This arrangement is illustrated in FIG. 2. Instead of the target, the laser pulses 12 from the laser source 11 are first directed to the moving and/or turning mirrors 21, which can be, for example as shown in the figure, a hexagonal and rotatable polygon having faces with mirror surfaces. The laser pulses 12 are reflected from the mirrors 21 to form a fan-shaped laser pulse formation (or distribution) and the reflected pulses are directed to the telocentric lens 22. By means of the telocentric lens 22, the laser pulse array can be aligned to form an array 23 of essentially parallel laser beams so that the laser beams hit the target 13 at the same angle. In the plane of observation of the example in FIG. 2, the said angle is 0° with respect to the normal of the surface. Detachment of the material in the same way at each point of incidence of the laser pulses is possible if the energy/intensity distribution of the laser pulses is the same at each point of incidence.

The laser beam array can also be generated by other means, e.g., a rotating monogon mirror, which directs the laser beams, for example, to an annular target, from which a ring shape material flow is formed.

In an application example a component of a lithium battery, Li-ion battery, or Li-ion capacitor is well suited for deposition so that material is unwound from a roll to be coated over a desired width in the deposition chamber. A view of principle is shown of this application alternative in FIG. 3. Material is directed at the desired coating width from one or several coating sources onto one or several surfaces of the object to be coated so that material is constantly unwound from the roll for coating and, after it has passed the deposition zone, the material is again collected to a roll. The method can be called a roll-to-roll method, as has already been stated above. In other words, the part 32 to be coated is initially wound in the roll 31a. The ablation apparatus including the laser sources 11 and the target materials 13 is included as has been stated above. The laser pulses 12 cause the material to detach as a flow 14 (i.e. in the form of a material flux) towards the material 32 to be coated, and as a result of adherence, the coated part 33 is produced. The coated web 33 is allowed to wind around the second roll 31b, the direction of motion of the web being from left to right in the situation illustrated in FIG. 3. The roll structures 31a, 31b can be motor-driven. Seen in the direction of depth in the figure (transverse direction), the object to be coated can be the entire area of the surface, or only part of the surface. Similarly, in the direction of motion of the web (machine direction), a desired part (length) of the web can be selected to be coated, or alternatively, the entire roll can be processed from the beginning to the end so that the web throughout the entire length of the roll becomes coated. In the case of a membrane material, either only one side or both sides can be coated entirely or, as described above, partially in the machine direction and/or transverse direction.

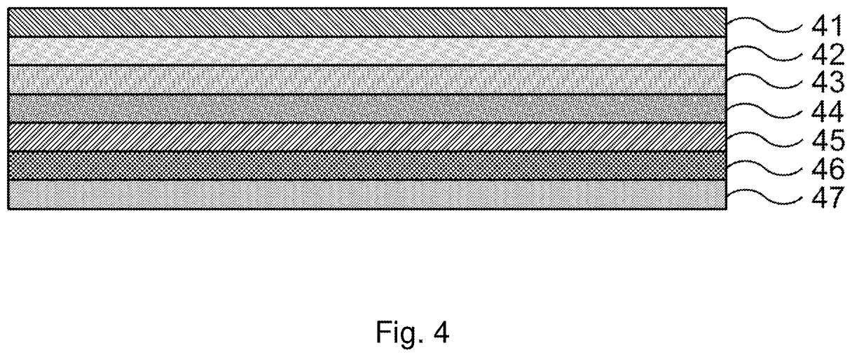

FIG. 4 illustrates the structure of an exemplary embodiment of a lithium battery in a simplified cross-sectional view in such a case that the deposition substrate is lithium foil. Of the parts, the first one from the top is the lithium foil 41, which can function as a current collector for the electric current in addition to being active anode material. Moving down, the next part is a protective layer 42, which can be for example intrinsically electrically insulating oxide, deposited on the lithium foil. A protective layer like this can be 1-1000 nm in thickness and most preferably 1-100 nm. Next there is the first solid-electrolyte layer 43, which can be coated with a protective layer 44. The fifth layer is the second solid-electrolyte layer 45 which is of different material than the first solid-electrolyte layer 43. The lowermost layers are active cathode material 46 and aluminium layer 47 which functions as current collector in the cathode side.

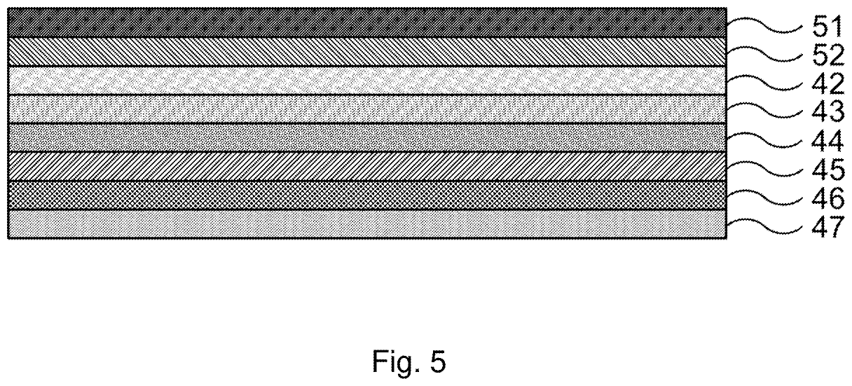

FIG. 5 illustrates the structure of an exemplary embodiment of a lithium battery in a simplified cross-sectional view in such a case that the deposition substrate is copper current collector foil 51, which is the first of the layers starting from the top. The structure is otherwise the same as in FIG. 4 but eight layers are depicted first of which layers is copper current collector 51 and lithium layer 52 is produced on the surface of the copper by means of coating.

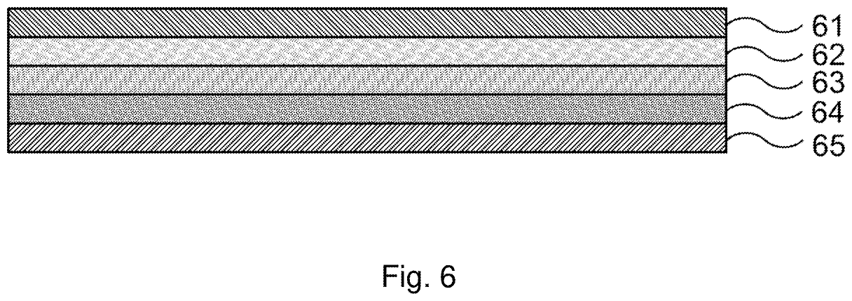

FIG. 6 illustrates the structure of an exemplary embodiment of anode-side of a lithium battery in a simplified cross-sectional view in such a case that the deposition substrate is separator membrane 61, which is the first of the layers starting from the top. The separator can be made of polymer, cellulose, ceramic, or glass fiber and can be coated with a ceramic layer 62. Advancing downwards in the image, the next part is an ion-conducting inorganic material layer 63. Next layer 64 is an optional protective layer which can be, for example, a thin layer of intrinsically electrically insulating oxide or, alternatively, lithium-compatible stable inorganic ion-conducting material. The last layer on the bottom is a deposited layer of lithium 65.

In FIGS. 4-6 the different layers and their interfaces have been presented as straight lines, but in reality, it might be beneficial for the structure and for the functionality of the battery that the different layers are at least partially interlaced and contact each other over a large surface area. In addition, the layer thicknesses are different for each layer, being 0.5 nm at minimum in the case of protective layer and 100 μm at maximum in the case of an electrode layer. Especially, the thickness of the lithium-metal anode layer is preferably less than 50 μm, more preferably 1-40 μm, and most preferably 1-20 μm. The ion-conducting inorganic material layer should be as thin as possible but thick enough to prevent direct contact between anode and cathode. The thickness of the ion-conducting inorganic material layer should be preferably less than 50 μm, more preferably less than 25 μm, and most preferably less than 10 μm. When functioning as a chemical protective layer, the ion-conducting inorganic material layer can have a thickness of 0.5-10 nm at minimum but even up to 100 nm.

FIG. 7a illustrates an example of a combinatorial coating method using two simultaneous material flows to form a composite coating. Here, two separate laser beams, i.e., the first laser pulse train 71a and the second laser pulse train 71b enter the arrangement. In the figure, the laser pulse trains are depicted as dashed lines, and the laser pulses enter the image area from the lower right-hand side. The laser pulse trains 71a-b are directed to hit the target material pieces, i.e. the first target 72a and the second target 72b. The material of the first target is different from the material of the second target. Preferentially, the target surface encountered by the laser pulses is set at an inclined direction with respect to the direction of the incoming laser pulses. Of these interactions, the material flows 73a and 73b, shown as linearly advancing and expanding material clouds in the figure, are formed as the result of laser ablation. Both these material flows comprise mostly particles in nonreactive form and, additionally, atoms and/or ions, but concerning different materials. The material flows advance simultaneously and partly within the same volume before hitting the lower surface of the substrate 75, thus forming the composite coating 74a which has mainly two different materials distributed homogeneously. The proportions of the different substances in the composite coating 74a can be varied, for example, by independently adjusting either one or both of the laser sources, which generate the laser beams 71a and 71b. The composite coating 74a, the term including also coatings composed of doped materials, is thus formed from the material flows 73a and 73b on the lower surface of the substrate 75 principally in one step and immediately as a finished coating.

FIG. 7b illustrates an example of a combinatorial coating method using two simultaneous material flows to form a compound coating. Here, two separate laser beams, i.e. the first laser pulse train 71c and the second laser pulse train 71d enter the arrangement, and these pulse trains are directed to hit the target material pieces, i.e. the first target 72c and the second target 72d. The material of the first target is different from the material of the second target. Of these interactions, the material flows 73c and 73d are formed as the result of laser ablation. Both these material flows comprise mostly components in reactive form but concerning different materials. The material flows advance simultaneously and partly within the same volume before hitting the lower surface of the substrate 75, thus forming the compound coating 74b which has mainly compound formed from two different materials. The proportions of the different substances in the compound coating 74b can be varied, for example, by independently adjusting either one or both of the laser sources, which generate the laser beams 71c and 71d. The compound coating 74b is thus formed from the material flows 73c and 73d on the lower surface of the substrate 75 principally in one step and immediately as a finished coating.

FIG. 8a illustrates the use of successive deposition stations to improve productivity. In this example, four deposition stations are shown, and each incoming laser beam (or pulse train) 81a-d is directed to the appropriate target 82a-d by a mirror (P, each beam having its own). In this situation, the roll-to-roll method or a substrate movable by other means can be used, and the movement of the substrate is directed from the left-hand side of the figure to the the right-hand side of the figure. The lower surface of the substrate 85 first encounters the first material flow 83a, of which the first coating layer 84a is formed. This first coating layer 84a again encounters the second material flow 83b as the substrate 85 moves to the right in the figure, and this way the second coating layer 84b is produced onto the first coating layer 84a. This process continues in the two remaining coating stations, and the final result is the substrate 85 which has encountered the four material flows 83a-d, and this coating has a layered structure 84a, 84b, 84c, 84d. The targets 82a-d can be of the same material, as shown in this figure.

FIG. 8b illustrates the use of successive coating stations to improve productivity in the manufacture of composite structures. This is otherwise similar to the situation in FIG. 8a, but now two different types of materials have been selected as the target material pieces 82A, 82B, and these are positioned alternately, one target to one coating station, and the next target being of the second material. In other words, seen from the left, the first and third target are of the same first material “A”, and the second and fourth target, respectively, are of the same second material “B”. The laser pulse trains 81a-d can still be controlled independently and directed on the targets by the mirrors P. This arrangement provides two different types of material flows 83A, 83B, which alternate. When the material flows hit the moving substrate 85, a new different layer is formed on top of the older layers, and the final result is the 4-layered composite structure 84A, 84B, 84A, 84B visible in the right-hand side edge of the figure. In this coating, the material layers thus alternate with each other.

FIG. 8c illustrates the use of successive coating stations to improve productivity in the manufacture of doped material. This arrangement is otherwise similar to the one in FIG. 8b, but here the first and third target 82C are made of the basic material, and the second and fourth target 82D, respectively, are made of the additive, i.e. doping material. The laser pulse trains 81a-d can still be controlled independently, and they can be directed on the targets by the mirrors P. This arrangement produces two material flows 83C, 83D of different types, which alternate. With the respective principle as above, the doped basic material now forms the coating to the substrate 85, and the relative proportion of doped material of the entire coating can be chosen by independently adjusting the laser parameters. In the coating layers, 84C represents the basic material layer and 84D the additive layer.

The combinatorial coating arrangements and coating stations according to FIGS. 7a-b and 8a-c can be combined such that, for example, in place of one or several of the coating stations in FIG. 8b, a coating arrangement of another type is selected when necessary, such as a combinatorial coating station comprising two or more targets according to the principle of the example presented in FIG. 7a. Successive and combinatorial coating arrangements can be combined also such that in place of one or several material sources, another suitable coating method, such as CVD, ALD, or PVD is used instead of pulsed laser ablation deposition.

In the following, features of the invention are further compiled in a list-type form in the way of a summary.

The invention relates to a method for manufacturing a component of an electrochemical energy storage device, such as lithium battery, lithium-ion battery, or lithium-ion capacitor, which component comprises lithium anode and ion-conducting inorganic material layer, the method comprising the steps of
directing laser pulses (12, 71a-d, 81a-d) to at least one target (13, 72a-d, 82a-d, 82A-D) containing constituent materials of an inorganic ion-conducting material—detaching at least one material (14, 73a-d, 83a-d, 83A-D) from at least one target (13, 72a-d, 82a-d, 82A-D) by laser ablation
directing at least one detached material (14, 73a-d, 83a-d, 83A-D) to the deposition substrate (15, 32, 75, 85) to at least one surface or part of the surface.

A characteristic feature of the invention is that the method further comprises the step
a component of an electrochemical energy storage device, such as lithium battery, lithium-ion battery, or lithium-ion capacitor, which component comprises lithium anode and ion-conducting inorganic material layer, is produced in such a way that at least one ion-conducting material layer is produced based on pulsed laser ablation deposition.

In an embodiment of the invention, the ion-conducting inorganic material layer is deposited on a porous polymer, cellulose, ceramic, or glass-fiber substrate by pulsed laser technology after which a lithium anode layer is produced on the surface of the ion-conducting inorganic layer.

In an embodiment of the invention, the porous substrate has been coated with a material containing at least 80 volume-% ceramic particles before the deposition of the ion-conducting inorganic material layer.

In an embodiment of the invention, the ion-conducting inorganic material layer comprises lithium, sulfur, and phosphorus a combined amount which corresponds to at least 70 weight-% and preferably more than 80 weight-% of the total amount of the ion-conducting inorganic material layer.

In an embodiment of the invention, on the other surface of the produced ion-conducting inorganic material layer, an inorganic material layer of at least 0.5 nm in thickness is deposited by chemical vapor deposition, atomic layer deposition, physical vapor deposition, or pulsed laser technology.

In an embodiment of the invention, the produced ion-conducting inorganic material layer is first formed at elevated temperature after which it is subjected to a separate heat treatment which turns the structure of the material layer crystalline in at least 5 volume-% from a depth of at least 100 nm.

In an embodiment of the invention, the produced ion-conducting inorganic material layer comprising lithium, sulfur, and phosphorus a combined amount of at least 70 weight-% is deposited on a lithium-metal layer, such that an inorganic material layer with thickness of 100 nm at most is between the lithium metal and the ion-conducting inorganic material layer, and this multi-layer structure is processed at a temperature higher than 80° C.

The method of the invention has the following advantages:
i. Components for high energy density Li-ion batteries can be manufactured as multi-layer structures in an environment where reactive materials such as lithium and solid electrolytes can be protected from contaminations and unfavorable surface reactions
ii. The use of binders and other electrochemically unnecessary materials can be avoided, which materials can interfere with the activity of electrochemical reactions in long-term operation
iii. Preventing the formation of hazardous reaction products, such as H2S released when solid electrolyte LPS reacts with water, occurring when battery chemicals react with the environment or with the liquids used in traditional processes
iv. The thickness of the lithium anode layer can be adjusted accurately
v. Producing very thin lithium anode layers with thickness of less than 20 μm which thickness is very difficult to reach by using rolled or extruded thin sheets or foils
vi. Multi-layer structures can be manufactured within the same controlled process environment without handling sensitive materials in oxidizing, nitriding, carbonizing or moisture containing environments
vii. A very good adhesion between different material layers can be generated by avoiding contamination of surfaces and by using high enough kinetic energy in the deposition process
viii. Ion-conducting layers able to prevent the growth of dendrites can be manufactured on the surface of a lithium-metal anode manufactured by using the same method (PLD) in a single process step
ix. Surface of a lithium-metal anode manufactured by rolling or extrusion can be cleaned from impurities and, for example, from reaction layers formed as a result from reaction with air by using pulsed laser technique
x. Ion-conducting layers with multi-layer structures can be manufactured of various materials on the surface and on top of lithium anodes manufactured by using different methods, thus maximizing ionic conductivity and ability to prevent the growth of dendrites as well as minimizing the stresses and detrimental interface reactions generated during manufacturing and operation
xi. Material layers without defects, such as pores or cracks, can be manufactured which improves the ability to prevent the growth of dendrites
xii. Amorphous coating layers without grain boundaries can be manufactured, which improves the ability to prevent the growth of dendrites
xiii. Laser technology can be applied also in post-processing of coating layer, i.a., in increasing the degree of crystallization by laser heat treatment
xiv. Also other methods than laser technology can be applied such as hot lamps, hot plates, or hot rolling for increasing the degree of crystallization
xv. Cold or hot forming can be used for densifying the structure, i.a., in the cases of solid electrolytes of LPS-system or solid electrolytes with thio-LISICON-structures or lithium metal
xvi. Use of chemicals, binders, bonding agents as well as water and solvents can be avoided because the method is dry and binders are not used
xvii. Use of binders can be avoided, which reduces the contamination of battery chemistry in long term operation
xviii. The correct composition of coating layers can be guaranteed by composition of target and by selection of process parameters
xix. Open area and porosity, and this way the contact area with electrolyte material, of the active electrode material can be adjusted by tuning laser parameters, background gas or its pressure, and the distance between the target and the substrate
xx. The amount of productional investments can be reduced
xxi. It is possible to manufacture batteries with a considerably higher energy density when compared to the conventional material solutions

In the invention, it is possible to combine individual features of the invention mentioned above and in the dependent claims into new combinations, in which two or several individual features can have been included in the same embodiment.

The present invention is not limited only to the examples shown, but many variations are possible within the scope of protection defined by the enclosed claims.

1. A method for manufacturing a component of an electrochemical energy storage device comprising a lithium battery, lithium-ion battery, or lithium-ion capacitor, the component comprises a lithium anode and ion-conducting inorganic material layer, the method comprising the steps of
directing laser pulses to at least one target containing constituent materials of an ion-conducting inorganic material;
detaching at least one material from at least one target by laser ablation;
directing at least one detached material to a deposition substrate to at least one surface or part of the surface;
processing at least one material layer by mechanical or thermomechanical treatment after the pulsed laser deposition.

2. The method according to claim 1, wherein the method includes assembly of a lithium battery, a Li-ion battery, or a Li-ion capacitor having on at least one surface of the lithium anode an ion-conducting inorganic material layer which is produced by pulsed laser deposition.

3. The method according to claim 1, wherein the surface of the lithium anode layer is processed by pulsed laser prior to coating the lithium anode layer with an ion-conducting inorganic material layer.

4. The method according to claim 1, wherein the lithium-anode layer is produced by pulsed laser deposition.

5. The method according to claim 1, the ion-conducting inorganic material layer is deposited on a porous polymer, cellulose, ceramic, or glass-fiber substrate by pulsed laser deposition, after which a lithium anode layer is produced on a surface of the ion-conducting inorganic material layer.

6. The method according to claim 5, wherein the porous substrate has been coated with a material containing at least 80 volume-% of ceramic particles before the deposition of the ion-conducting inorganic material layer.

7. The method according to claim 1, wherein, the lithium anode layer is 1-40 μm in thickness.

8. The method according to claim 1, wherein the ion-conducting inorganic material layer is deposited by using pulsed laser deposition such that a duration of the laser pulses is 100 ns at most.

9. The method according to claim 1, wherein the thickness of the ion-conducting inorganic material layer is at most 25 μm.

10. The method according to claim 1, wherein the thickness of the ion-conducting inorganic material layer is at most 10 μm.

11. The method according to claim 1, wherein the ion-conducting inorganic material layer is an oxide of the type Li-M-N-O, in which M and N are different metals.

12. The method according to claim 1, wherein the ion-conducting inorganic material layer comprises lithium, sulfur, and phosphorus in a combined amount which corresponds to at least 70 weight-% of a total amount of the ion-conducting inorganic material layer.

13. The method according to claim 1, wherein on at least one surface and on top of the lithium metal anode are two different material layers, of which at least one is an ion-conducting inorganic material.

14. The method according to claim 1, wherein, at least one material layer is processed by thermomechanical treatment at a temperature above 80° C.

15. The method according to claim 14, wherein the thermomechanical treatment is performed for an ion-conducting inorganic material layer which comprises lithium, sulfur, and phosphorus in a combined amount which corresponds to at least 70 weight-% of a total amount of the ion-conducting inorganic material layer.

16. The method according to claim 14, wherein the thermomechanically processed material is heat treated at a temperature above 150° C.

17. The method according to claim 16, wherein heat treatment after the thermomechanical treatment is performed at least partially by using laser radiation.

18. The method according to claim 16, wherein the heat treatment after the thermomechanical treatment turns a structure of the ion-conducting inorganic material layer crystalline in at least 5 volume-% from a depth of at least 100 nm.

19. The method according to claim 14, wherein the thermomechanical processing is performed such that the material to be processed has at least layers of ion-conducting inorganic material and lithium.

20. The method according to claim 1, wherein on the other surface of the ion-conducting inorganic material layer comprising lithium, sulfur, and phosphorus a combined amount of at least 70 weight-%, an inorganic material layer of at least 0.5 nm in thickness is deposited by chemical vapor deposition, atomic layer deposition, physical vapor deposition, or pulsed laser deposition.

21. The method according to claim 1, wherein the ion-conducting inorganic material layer comprising lithium, sulfur, and phosphorus in a combined amount of at least 70 weight-% is amorphous such that the ion-conducting inorganic material layer comprises crystalline material 5 weight-% at most.

22. The method according to claim 1, wherein the ion-conducting inorganic material layer comprising in total at least 70 weight-% of lithium, sulfur, and phosphorus is deposited on a lithium layer, such that an inorganic material layer with thickness of 100 nm at most is between the lithium and the ion-conducting inorganic material layers, and the multi-layer structure is processed at a temperature higher than 80° C.

23. The method according to claim 22, wherein the multi-layer structure is thermally treated at a temperature higher than 150° C. after the thermomechanical processing.

24. An electrochemical energy storage device utilizing lithium, the device comprises:
a. a cathode material, and
b. a lithium anode,
c. at least on one surface of the lithium anode an ion-conducting inorganic material layer, and
d. in manufacturing of the ion-conducting inorganic material layer the method according to claim 1 has been utilized.
